(19) United States
(12) Patent Application Publication
(10) Pub. No.: US 2024/0401229 A1
(43) Pub. Date: Dec. 5, 2024

(54) COMPOSITE SUBSTRATE AND MANUFACTURING METHOD THEREOF

(71) Applicant: ROHM CO., LTD., Kyoto (JP)

(72) Inventors: Keiju SATO, Kyoto (JP); Makoto TAKAMURA, Kyoto (JP)

(73) Assignee: ROHM CO., LTD., Kyoto (JP)

(21) Appl. No.: 18/669,362

(22) Filed: May 20, 2024

(30) Foreign Application Priority Data
Jun. 5, 2023 (JP) 2023-092684

(51) Int. Cl. C30B 25/18; C30B 29/02; C30B 29/58; C30B 29/60; C30B 33/02

(52) U.S. Cl. CPC C30B 25/18; C30B 29/02; C30B 29/58; C30B 29/60; C30B 33/02

(57) ABSTRACT

The present disclosure provides a composite substrate. The composite substrate includes: a SiC single crystal substrate having an off-angle; and a carbon-containing layer including a laminate of a reconstructed surface layer and a graphene layer, or a graphene layer disposed in contact with a surface of the SiC single crystal substrate. When an outermost surface of the SiC single crystal substrate is a Si-terminated surface, the laminate is disposed above the SiC single crystal substrate, and the graphene layer of the laminate is one or two layers. When the outermost surface of the SiC single crystal substrate is a C-terminated surface, one or two graphene layers are arranged above the SiC single crystal substrate.

### TECHNICAL FIELD

The present disclosure relates to a composite substrate and a manufacturing method thereof.

### BACKGROUND

Among methods for producing graphene, there is known a method of removing an oxide film formed by natural oxidation and covering the surface of a silicon carbide (SiC) single crystal substrate to expose the Si surface of the SiC single crystal substrate. The exposed SiC single crystal substrate is heated (thermally decomposed) in a vacuum or an inert gas such as argon (Ar). By heating in a vacuum or an inert gas such as argon (Ar), silicon (Si) sublimates and the remaining carbon (C) self-assembles, so that graphene is formed in a stacked manner on the SiC single crystal substrate.

### PRIOR ART DOCUMENTS

### Patent Document

[Patent Document 1] International Publication No. 2010/023934

### BRIEF DESCRIPTION OF THE DRAWINGS

FIG. 1 shows a cross-sectional view of a composite substrate according to the embodiment.

FIG. 2 shows a cross-sectional view of a composite substrate according to Modified example 1.

FIG. 3 shows a cross-sectional view of a composite substrate according to Modified example 2.

FIG. 4A is a cross-sectional view showing one step of the manufacturing steps of the composite substrate according to Modified example 2 (Part 1).

FIG. 4B is a cross-sectional view showing one step of the manufacturing steps of the composite substrate according to Modified example 2 (Part 2).

FIG. 4C is a cross-sectional view showing one step of the manufacturing steps of the composite substrate according to Modified example 2 (Part 3).

FIG. 4D is a cross-sectional view showing one step of the manufacturing steps of the composite substrate according to Modified example 2 (Part 4).

### DETAILED DESCRIPTION OF THE EMBODIMENTS

Next, embodiments will be described with reference to the accompanying drawings. In the description of the drawings described below, the same or similar symbols are assigned to the same or similar parts. The drawings are schematic. In addition, the embodiments shown below exemplify devices or methods for embodying technical ideas, and do not specify the materials, shapes, structures, arrangements, etc. of components. Various changes may be added to the embodiment.

The composite substrate of the present embodiment will be described using the accompanying drawings.

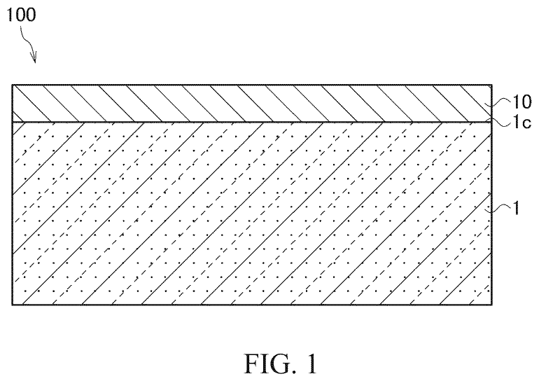

FIG. 1 shows a cross-sectional view of a composite substrate 100 according to the present embodiment.

The composite substrate 100 includes a SiC single crystal substrate 1 having an off-angle; and a carbon-containing layer disposed in contact with a surface of a substrate of the SiC single crystal substrate 1. In the present embodiment, the outermost surface of the SiC single crystal substrate 1 is a carbon (C)-terminated surface 1c, and the carbon-containing layer in contact with the C-terminated surface 1c is provided with one or two layers of graphene layer 10.

The “off-angle” in the present disclosure refers to the rotation angle θ when the grown crystal is rotated at a certain angle along the in-plane in the C-axis direction (the direction perpendicular to the substrate plane, the film thickness direction) and cut. The off-angle of the SiC single crystal substrate 1 is preferably between about 0.5° and about 10°, and more preferably between about 4° and about 8°.

The SiC single crystal substrate 1 may have a crystalline structure of either a hexagonal (4H, 6H) crystal or a cubic (3C) crystal. For example, the SiC single crystal substrate 1 containing a hexagonal (4H) crystal is obtained by the following method: sublimating SiC powder as a raw material in a graphite crucible filled with an inert gas such as nitrogen (N₂) gas, and performing recrystallization to obtain a SiC seed crystal under a temperature controlled to be lower than that of the raw material powder (modified from Lely method (seeded sublimation recrystallization method)). At this time, impurities that determine the conductivity type of the SiC single crystal substrate 1 may be added.

The graphene layer 10 has a single-layer structure of one layer or a laminated structure of two layers. The number of the graphene layer 10 that serves as the carbon-containing layer is one or two, so that the difference in the number of the carbon-containing layer is one or less. In addition, the number of the carbon-containing layer can be observed by, for example, Raman spectroscopy, Transmission Electron Microscope (TEM), etc. When observing a wide range, it is preferable to use Raman imaging. From the viewpoint of the difference in the number of the carbon-containing layer, the number of the graphene layer 10 is preferably one. If the difference in the number of the carbon-containing layer is one or less, the crystal growth of the epitaxial layer that can be formed later will be improved.

Generally speaking, during the formation of the carbon-containing layer such as the graphene layer on the SiC single crystal substrate, by thermal decomposition of the SiC single crystal substrate, the Si atoms of the SiC single crystal substrate are sublimated and the remaining carbons (C) self-assemble, so that the graphene layers will be formed in a stacked manner on the SiC single crystal substrate.

In this embodiment, in order to reduce the difference in the number of the carbon-containing layer, in addition to supplying carbon from the SiC single crystal substrate as described below, a deposition method that can be controlled at the molecular layer level is further used to deposit a thin film containing carbon on the SiC single crystal substrate to serve as a new source of carbon. Next, the thin film is carbonized by heat treatment to form the carbon-containing layer, such as the graphene layer 10. Through these steps, the growth of the carbon-containing layer can be promoted before step aggregation of the SiC single crystal substrate occurs.

Here, when the carbon-containing layer is formed and the supply of carbon relies only on the SiC single crystal substrate, the in-plane difference of the carbon-containing layer becomes increased due to the difference in local thermal decomposition rate. Therefore, by supplying carbon from the outside while forming the carbon-containing layer as in the present embodiment, differences in the carbon-containing layer can be improved by relatively suppressing the effect induced by the thermal decomposition of the SiC single crystal substrate when the same one layer is obtained. In addition, since the carbon-containing layer with increased crystallinity can be formed, it is possible to reduce difference in epitaxial film growth of the semiconductor device when a composite substrate including the carbon-containing layer is used as a material for the semiconductor device or the like.

According to the present embodiment, it is possible to obtain a composite substrate 100 in which the difference in the number of the carbon-containing layer formed on the SiC single crystal substrate is reduced.

In the composite substrate 100, the outermost surface of the SiC single crystal substrate 1 is the C-terminated surface 1c, but it is not limited thereto. For example, various modified examples as shown below are also possible.

### Modified Example 1

The structure of a composite substrate 100A according to Modified example 1 will be described. In Modified example 1, the common aspects with the composite substrate 100 shown in FIG. 1 are referred to the above description, and different aspects will be described below.

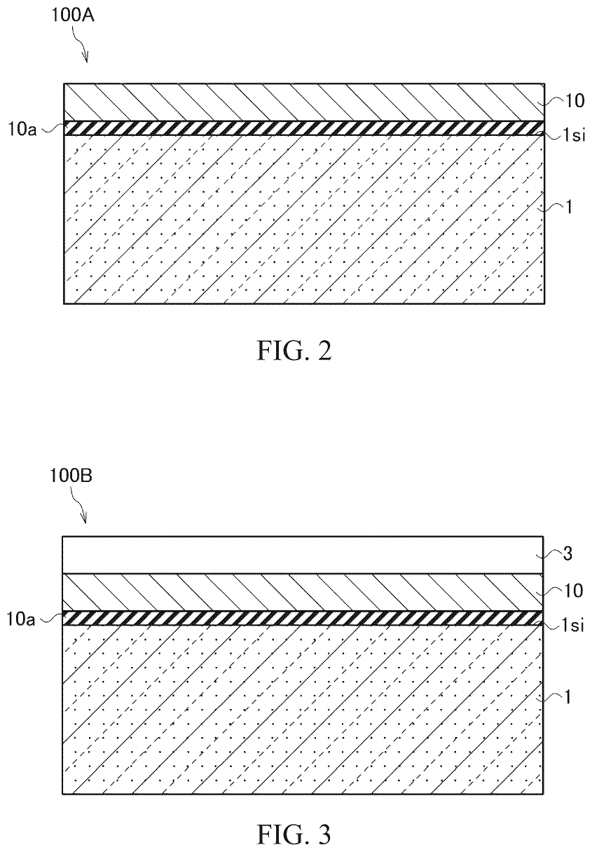

FIG. 2 is a cross-sectional view of the composite substrate 100A of Modified example 1. The composite substrate 100A of Modified example 1 is different from the composite substrate 100 shown in FIG. 1 in the following aspects: the outermost surface of the SiC single crystal substrate 1 is a silicon (Si)-terminated surface 1si, and the carbon-containing layer in contact with the Si-terminated surface 1si is a laminate in which a reconstructed surface layer 10a and the graphene layer 10 are laminated.

In the composite substrate 100A, the outermost surface of the SiC single crystal substrate 1 is the Si-terminated surface Isi. Therefore, when the graphene layer 10 is formed on the surface of the SiC single crystal substrate 1, the reconstructed surface layer 10a is formed on the surface of the SiC single crystal substrate 1, and the graphene layer 10 is formed on the reconstructed surface layer 10a. The reconstructed surface layer 10a plays a role in easing the lattice mismatch with the graphene layer 10, and is also called a buffer layer or layer 0 of the graphene layer.

In Modified example 1, when forming the carbon-containing layer, carbon is also supplied from the outside in addition to the SiC single crystal substrate. Therefore, even when the same one layer is obtained, the difference in the carbon-containing layer is also improved by relatively suppressing the effect induced by the thermal decomposition of the SiC single crystal substrate.

### Modified Example 2

The structure of the composite substrate 100B according to Modified example 2 will be described. In Modified example 2, the common aspects with the composite substrate 100A shown in FIG. 2 are referred to the above description, and different aspects will be described below.

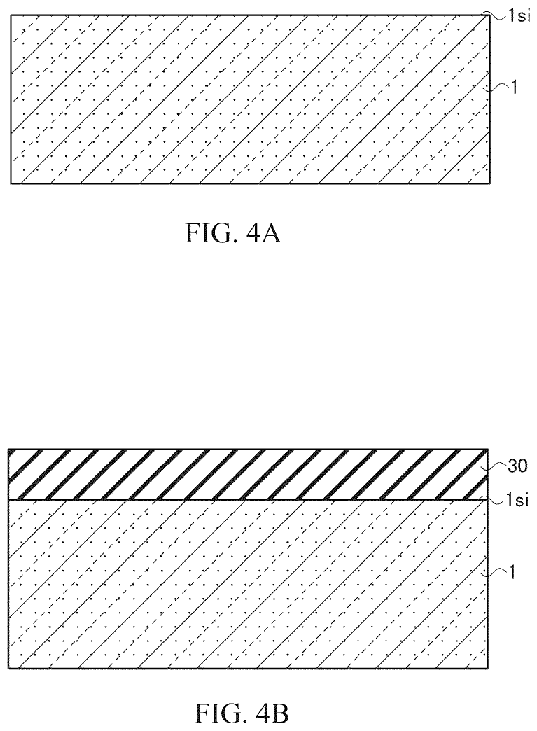

FIG. 3 is a cross-sectional view of a composite substrate 100B according to Modified example 2. The composite substrate 100B of Modified example 2 is different from the composite substrate 100A shown in FIG. 2 in that it includes an epitaxial layer 3 disposed on the graphene layer 10.

In the composite substrate 100B, by using the SiC single crystal substrate 1 having an off-angle, the crystal type of the SiC single crystal substrate 1 is reflected to the crystal growth of the epitaxial layer 3 via the graphene layer 10. Therefore, the epitaxial layer 3 of a single crystal having the same crystal type as that of the single crystal, that is SiC, of the SiC single crystal substrate 1 can be formed. From the viewpoint of crystal growth of the epitaxial layer 3, the off-angle is preferably between about 0.5° and about 10°, and more preferably between about 4° and about 8°.

In Modified example 2, when forming the carbon-containing layer, carbon is also supplied from the outside in addition to the SiC single crystal substrate. Therefore, even when the same one layer is obtained, differences in the carbon-containing layer are also improved by relatively suppressing the effect induced by the thermal decomposition of the SiC single crystal substrate. Compared with the composite substrate 100, the composite substrate 100B is also configured to have a reconstructed surface layer 10a, so it is easy to control the number of the graphene layer. In addition, the difference in the number of the graphene layer is reduced, so the crystallinity of the epitaxial layer 3 can be improved. In other words, the same type of crystal as that of the SiC single crystal substrate can be grown in the graphene layer.

### (Method for Manufacturing Composite Substrate)

Next, an example of a method of manufacturing a composite substrate will be described. Here, a method of manufacturing the composite substrate 100B will be described.

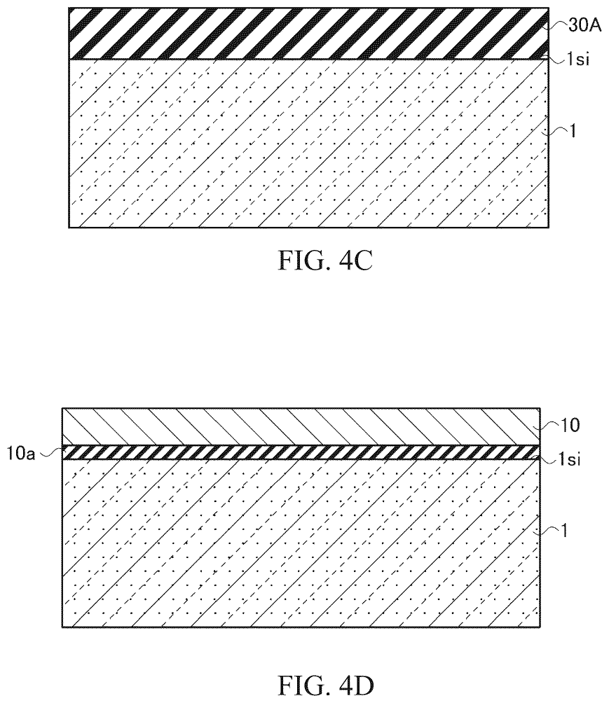

First, as shown in FIG. 4A, hydrofluoric acid is used on the Si-terminated surface 1si of the SiC single crystal substrate 1 to remove the natural oxide film from the SiC single crystal substrate 1. For example, a 4H—SiC substrate having an off-angle of 4° can be used as the SiC single crystal substrate 1. The size of the SiC single crystal substrate 1 is not particularly limited, and for example, a size of 10 mm2 can be used.

Next, as shown in FIG. 4B, a thin film 30 containing carbon is deposited on the SiC single crystal substrate 1 from which the natural oxide film has been removed. The thin film 30 is deposited using a deposition method that can be controlled at the molecular level. For the thin film 30, physical vapor growth method, chemical vapor growth method, wet deposition method, etc. can be used, for example. More specifically, the Langmuir-Blodgett method or the evaporation polymerization method can be used.

The thin film 30 may also be a Langmuir-Blodgett film using the Langmuir-Blodgett method or a self-assembled monomolecular film. In addition, the thin film 30 may include a molecular film having a weight-average molecular weight between about 100 and about 1,000. Examples of the molecular film having a weight-average molecular weight between about 100 and about 1,000 include saturated fatty acids, such as stearic acid (C₁₇H₃₅COOH), palmitic acid (C₁₅H₃₁COOH), etc.

The thin film 30 functions as a supply source of carbon for forming the carbon-containing layer such as the graphene layer. The thickness of the thin film 30 only needs to be sufficient to function as a carbon supply source. The thickness of the thin film 30 may be, for example, between about 0.3 nm and about 100 nm, between about 1 nm and about 90 nm, or between about 10 nm and about 80 nm.

Here, stearic acid (C₁₇H₃₅COOH) is dissolved in hexane at a concentration of 1 mM to obtain a dissolution solution, and the SiC single crystal substrate 1 from which the natural oxide film has been removed is immersed in a solution obtained by adding the dissolution solution dropwise into pure water. By pulling up vertically and drying, the SiC single crystal substrate 1 is covered with a monomolecular film, which serves as the thin film 30. The drying time is, for example, 60 minutes. Furthermore, the SiC single crystal substrate 1 covered with the monomolecular film is placed in a high-frequency induction heating furnace and evacuated. Evacuation can be performed, for example, until it becomes 1×10⁻³ N/m² or less.

Next, as shown in FIG. 4C, the SiC single crystal substrate 1 is subjected to a first heat treatment to carbonize the thin film 30 to form a thin film 30A. The first heat treatment is performed, for example, in a vacuum atmosphere equal to or less than 1×10⁴ N/m² or less at a temperature between about 300° C. and about 1,000° C., or in an inert gas atmosphere between about 1×10⁴ N/m² and about 1×10⁶ N/m². An example of the inert gas is argon gas.

Here, after covering the SiC single crystal substrate 1 with the monomolecular film as the thin film 30, an inert gas such as argon can be used for flushing, and after reaching atmospheric pressure, the SiC single crystal substrate 1 is heat-treated in an inert gas environment to carbonize the monomolecular film, thereby forming the thin film 30. The heat treatment temperature is, for example, 400° C.

In addition, the thin film 30 may be further subjected to heat treatment prior to the first heat treatment. As to this heat treatment, for example, the temperature increase rate may be between about 100° C./min and about 18,000° C./min, and resistance heating, lamp annealing, or high-frequency induction heating may be used. By subjecting the thin film 30 to this heat treatment, the thin film 30 can be efficiently carbonized in the first heat treatment.

Next, as shown in FIG. 4D, the SiC single crystal substrate 1 on which the thin film 30A is laminated is subjected to a second heat treatment to form a carbon-containing layer on the SiC single crystal substrate 1 using the carbon supplied by the thin film 30A. The carbon-containing layer includes a laminate, which includes a reconstructed surface layer 10a in contact with the Si-terminated surface 1Si of the SiC single crystal substrate 1 and a graphene layer 10 in contact with the reconstructed surface layer 10a.

The second heat treatment is performed at a temperature between about 1,000° C. and about 2,000° C., for example. Here, as the heat treatment, the SiC single crystal substrate 1 on which the thin film 30A is laminated is heated at 1600° C. for 5 minutes in a vacuum atmosphere equal to or less than 1×10⁴ N/m², so that the carbon-containing layer is formed on the surface of the single crystal substrate 1. The temperature increase rate at this time is, for example, 400° C./second. The formed carbon-containing layer has, for example, an area ratio of only the reconstructed surface layer 10a and the laminate including the reconstructed surface layer 10a and the graphene layer 10 of 80:20.

Next, as shown in FIG. 3, the epitaxial layer 3 is formed on the graphene layer 10 included in the carbon-containing layer. Through the above operations, the composite substrate 100B is completed. The formation (deposition) method of the epitaxial layer 3 is not particularly limited, and for example, physical vapor growth method, chemical vapor growth method, etc. can be used. In addition, the epitaxial layer 3 can be formed at a substrate temperature between about 1,000° C. and about 2,000° C.

The source gas used to form the epitaxial layer 3 is not particularly limited. For example, the volume ratio of propane (C₃H₈) and silane (SiH₄) set to 1:3 can be used. In addition, silane (SiH₄) can be used as the precursor of Si, and propane (C₃H₈) can be used as the precursor of C. Furthermore, argon gas that suppresses etching of the graphene layer 10 may be used as a carrier gas for transporting the source gas.

The thickness of the epitaxial layer 3 is not particularly limited, and may be, for example, 500 nm.

### OTHER EMBODIMENTS

As mentioned above, several embodiments have been described, but the statements and drawings that form part of the disclosure are illustrative and should not be understood as limiting. Various alternative embodiments, implementations, and operational techniques will be apparent to those skilled in the art from the present disclosure. In this way, the embodiments include various embodiments not described here.

### EXAMPLE OF EMBODIMENTS

Examples of embodiments are listed below. This embodiments are not limited to the following examples.

### Note 1

A method of manufacturing a composite substrate 100, 100A or 100B, comprising: depositing a thin film 30 containing carbon on a SiC single crystal substrate 1 using a deposition method that is controllable at a molecular layer level; and
forming a carbon-containing layer containing a laminate or a graphene layer 10 in which a restructured surface layer 10a and a graphene layer 10 are laminated on the SiC single crystal substrate 1 by a heat treatment and using the carbon supplied from the thin film 30, wherein
a difference in a number of carbon-containing layers on the SiC single crystal substrate 1 is equal to or less than one layer.

### Note 2

The method of manufacturing the composite substrate 100, 100A or 100B of [Note 1], wherein the thin film 30 includes a molecular film having a weight-average molecular weight between about 100 and about 1000.

### Note 3

The method of manufacturing the composite substrate 100, 100A or 100B of [Note 1] or [Note 2], wherein the thin film 30 is a Langmuir-Blodgett film or a self-assembled monolayer.

### Note 4

The method of manufacturing the composite substrate 100, 100A or 100B of any one of [Note 1] to [Note 3], wherein the deposition of the thin film 30 is performed by a method selected from a group including physical vapor deposition, chemical vapor deposition and wet deposition.

### Note 5

The method of manufacturing the composite substrate 100, 100A or 100B of [Note 4], wherein the thin film 30 is deposited by a Langmuir-Blodgett method or a vapor deposition polymerization method.

### Note 6

The method of manufacturing the composite substrate 100, 100A or 100B of any one of [Note 1] to [Note 5], wherein the thin film 30 has a thickness between about 0.3 nm and about 100 nm.

According to [Note 1] to [Note 6], when forming the carbon-containing layer, by supplying carbon from outside in addition to from the SiC single crystal substrate, variations in the carbon-containing layer are improved. Furthermore, when the composite substrates 100, 100A, and 100B including the carbon-containing layer are used as a material for a semiconductor device or the like, variations in epitaxial film growth in the semiconductor device can be reduced.

### Note 7

The method of manufacturing the composite substrate 100, 100A or 100B of any one of [Note 1] to [Note 6], wherein
the heat treatment includes a first heat treatment performed in a vacuum atmosphere or an inert gas atmosphere at a temperature between about 300° C. and about 1000° C., and
the thin film 30 is carbonized in the first heat treatment.

### Note 8

The method of manufacturing the composite substrate 100, 100A or 100B of [Note 7], wherein prior to the first heat treatment, a temperature increase rate is between about 100° C./min and about 18000° C./min, and
the heat treatment is performed on the thin film 30 by one selected from a group including resistance heating, lamp annealing and high frequency induction heating.

### Note 9

The method of manufacturing the composite substrate 100, 100A or 100B of [Note 7] or [Note 8], wherein the first heat treatment is performed
in a vacuum atmosphere equal to or less than 1×10⁴ N/m² or
in an inert gas atmosphere between about 1×10 N/m² and about 1×10⁶ N/m².

### Note 10

The method of manufacturing the composite substrate 100, 100A or 100B of any one of [Note 7] to [Note 9], wherein
the heat treatment includes a second heat treatment performed at a temperature between about 1000° C. and about 2000° C. after the first heat treatment, and
in the second heat treatment, the thin film 30A is formed into the carbon-containing layer.

According to [Note 7] to [Note 10], by controlling the heat treatment conditions, it is possible to efficiently carbonize the thin film 30 and form a carbon-containing layer on the SiC single crystal substrate 1 using carbon supplied from the thin film 30.

### Note 11

The method of manufacturing the composite substrate 100B of any one of [Note 1] to [Note 10], after forming the thin film 30 on the carbon-containing layer, further comprising forming an epitaxial layer 3 grown through the carbon-containing layer on the SiC single crystal substrate 1.

### Note 12

The method of manufacturing the composite substrate 100B of [Note 11], wherein a deposition of the epitaxial layer 3 is performed by a method selected from a group including physical vapor deposition and chemical vapor deposition.

### Note 13

The method of manufacturing the composite substrate 100B of [Note 11] or [Note 12], wherein the epitaxial layer 3 is formed at a substrate temperature between about 1000° C. and about 2000° C.

According to [Note 11] to [Note 13], there is little variation in the number of graphene layers, and the crystallinity of the epitaxial layer 3 can be improved.

### Note 14

A composite substrate 100, 100A or 100B, comprising:
a SiC single crystal substrate 1, having an off-angle; and
a carbon-containing layer, including a laminate of a reconstructed surface layer 10a and a graphene layer 10, or a graphene layer 10, disposed in contact with a surface of the SiC single crystal substrate 1, wherein
when an outermost surface of the SiC single crystal substrate 1 is a Si-terminated surface 1si, the laminate is disposed above the SiC single crystal substrate 1, and the graphene layer 10 of the laminate is one or two layers, and
when the outermost surface of the SiC single crystal substrate 1 is a C-terminated surface 1c, one or two graphene layers 10 are arranged above the SiC single crystal substrate 1.

### Note 15

The composite substrate 100, 100A or 100B of [Note 14], wherein the off-angle is between about 0.5° and about 10°.

### Note 16

The composite substrate 100, 100A or 100B of [Note 14] or [Note 15], wherein the SiC single crystal substrate 1 has a crystalline structure of a hexagonal crystal or a cubic crystal.

### Note 17

The composite substrate 100, 100A or 100B of any one of [Note 14] to [Note 16], wherein a number of graphene layers 10 included in the carbon-containing layer is one.

According to [Note 14] to [Note 17], when forming the carbon-containing layer, by supplying carbon from outside in addition to from the SiC single crystal substrate, variations in the carbon-containing layer can be improved. Furthermore, when the composite substrates 100, 100A, and 100B including the carbon-containing layer are used as a material for a semiconductor device or the like, variations in epitaxial film growth in the semiconductor device can be reduced.

### Note 18

The composite substrate 100B of any one of [Note 14] to [Note 17], further comprising:
an epitaxial layer 3, disposed above the graphene layer 10 included in the carbon-containing layer, wherein
the epitaxial layer 3 has a same crystal system as a same crystal system of the SiC single crystal substrate 1.

According to [Note 18], the graphene layer 10 can improve crystallinity of the epitaxial layer 3.

1. A method of manufacturing a composite substrate, comprising:
depositing a thin film containing carbon on a SiC single crystal substrate using a deposition method that is controllable at a molecular layer level; and
forming a carbon-containing layer containing a laminate or a graphene layer in which a restructured surface layer and a graphene layer are laminated on the SiC single crystal substrate by a heat treatment and using the carbon supplied from the thin film, wherein
a difference in a number of carbon-containing layers on the SiC single crystal substrate is equal to or less than one layer.

2. The method of claim 1, wherein the thin film includes a molecular film having a weight-average molecular weight between about 100 and about 1000.

3. The method of claim 1, wherein the thin film is a Langmuir-Blodgett film or a self-assembled monolayer.

4. The method of claim 1, wherein the deposition of the thin film is performed by a method selected from a group including physical vapor deposition, chemical vapor deposition and wet deposition.

5. The method of claim 4, wherein the thin film is deposited by a Langmuir-Blodgett method or a vapor deposition polymerization method.

6. The method of claim 1, wherein the thin film has a thickness between about 0.3 nm and about 100 nm.

7. The method of claim 1, wherein
the heat treatment includes a first heat treatment performed in a vacuum atmosphere or an inert gas atmosphere at a temperature between about 300° C. and about 1000° C., and
the thin film is carbonized in the first heat treatment.

8. The method of claim 7, wherein
prior to the first heat treatment, a temperature increase rate is between about 100° C./min and about 18000° C./min, and
the heat treatment is performed on the thin film by one selected from a group including resistance heating, lamp annealing and high frequency induction heating.

9. The method of claim 7, wherein the first heat treatment is performed
in a vacuum atmosphere equal to or less than 1×10⁴ N/m² or
in an inert gas atmosphere between about 1×10 N/m² and about 1×10⁶ N/m².

10. The method of claim 7, wherein
the heat treatment includes a second heat treatment performed at a temperature between about 1000° C. and about 2000° C. after the first heat treatment, and
in the second heat treatment, the thin film is formed into the carbon-containing layer.

11. The method of claim 1, after forming the thin film on the carbon-containing layer, further comprising forming an epitaxial layer grown through the carbon-containing layer on the SiC single crystal substrate.

12. The method of claim 11, wherein a deposition of the epitaxial layer is performed by a method selected from a group including physical vapor deposition and chemical vapor deposition.

13. The method of claim 11, wherein the epitaxial layer is formed at a substrate temperature between about 1000° C. and about 2000° C.

14. A composite substrate, comprising:
a SiC single crystal substrate, having an off-angle; and
a carbon-containing layer, including a laminate of a reconstructed surface layer and a graphene layer, or a graphene layer, disposed in contact with a surface of the SiC single crystal substrate, wherein
when an outermost surface of the SiC single crystal substrate is a Si-terminated surface, the laminate is disposed above the SiC single crystal substrate, and the graphene layer of the laminate is one or two layers, and
when the outermost surface of the SiC single crystal substrate is a C-terminated surface, one or two graphene layers are arranged above the SiC single crystal substrate.

15. The composite substrate of claim 14, wherein the off-angle is between about 0.5° and about 10°.

16. The composite substrate of claim 14, wherein the SiC single crystal substrate has a crystalline structure of a hexagonal crystal or a cubic crystal.

17. The composite substrate of claim 14, wherein a number of graphene layers included in the carbon-containing layer is one.

18. The composite substrate of claim 14, further comprising:
an epitaxial layer, disposed above the graphene layer included in the carbon-containing layer, wherein
the epitaxial layer has a same crystal system as a same crystal system of the SiC single crystal substrate.
